(19) United States
(12) Patent Application Publication
(10) Pub. No.: US 2023/0236507 A1
(43) Pub. Date: Jul. 27, 2023

(54) METHOD OF MANUFACTURING SEMICONDUCTOR STRUCTURE AND PHOTORESIST COMPOSITION

(71) Applicant: TAIWAN SEMICONDUCTOR MANUFACTURING COMPANY, LTD., Hsinchu (TW)

(72) Inventors: Tzu-Yang LIN, Tainan City (TW); Chen-Yu LIU, Kaohsiung City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 17/585,033

(22) Filed: Jan. 26, 2022

(51) Int. Cl. G03F 7/039; G03F 7/004; G03F 7/20; C25D 7/12; G03F 7/32; G03F 7/34

(52) U.S. Cl. CPC G03F 7/0392; G03F 7/0045; G03F 7/2006; C25D 7/12; G03F 7/322; G03F 7/34

(57) ABSTRACT

A method of manufacturing a semiconductor structure includes the following operations. A photoresist layer is formed on a metal layer, in which the photoresist layer includes an additive selected from the group consisting of a first heterocyclic compound containing a triazole ring, a second heterocyclic compound containing an imidazole ring, biphenyl thiol, biphenyl dithiol, benzenethiol, and benzenedithiol. The photoresist layer is exposed to an actinic radiation. The photoresist layer is developed by a developer to form holes in the photoresist layer. Redistribution lines are formed in the holes by an electroplating process.

### BACKGROUND

The semiconductor integrated circuit (IC) industry has experienced rapid growth. Technological advances in IC materials and design have produced generations of ICs where each generation has smaller and more complex circuits than the previous generation. For the most part, improvement in integration density has come from repeated reductions in feature size. Functional density (i.e., the number of interconnected devices per chip area) has generally increased while geometry size (i.e., the smallest component (or line) that can be created using a manufacturing process) has decreased. This scaling down process generally provides benefits by increasing production efficiency and lowering associated costs. However, such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating a method of manufacturing a semiconductor structure in accordance with some embodiments.

FIGS. 2-14 show exemplary sequential processes for manufacturing a semiconductor structure in accordance with some embodiments.

FIG. 15 is a flowchart illustrating a method of manufacturing a semiconductor structure in accordance with some embodiments.

FIGS. 16-19 show exemplary sequential processes for manufacturing a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

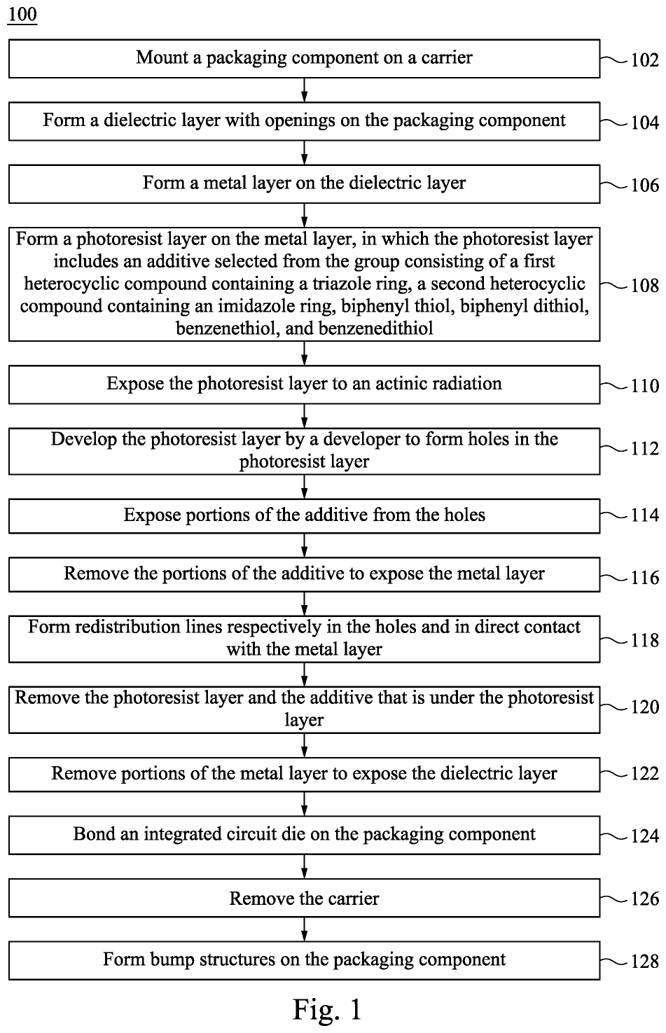

FIG. 1 illustrates a method 100 for manufacturing a semiconductor structure in accordance with some embodiments. The method 100 includes operations 102, 104, 106, 108, 110, 112, 114, 116, 118, 120, 122, 124, 126, and 128. Although the method 100 is illustrated and/or described as a series of operations or events, it will be appreciated that the method 100 is not limited to the illustrated ordering or operations. Thus, in some embodiments, the operations may be carried out in different orders than illustrated, and/or may be carried out concurrently. Further, in some embodiments, the illustrated operations or events may be subdivided into multiple operations or events, which may be carried out at separate times or concurrently with other operations or sub-operations. In some embodiments, some illustrated operations or events may be omitted, and other un-illustrated operations or events may be included.

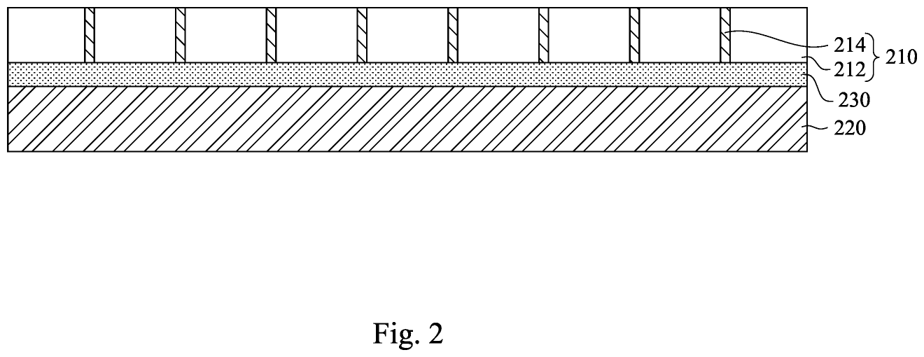

FIGS. 2-14 show exemplary sequential processes for manufacturing a semiconductor structure in accordance with some embodiments.

In the operation 102 of FIG. 1, a packaging component is mounted on a carrier. FIG. 2 illustrates a cross-sectional view of some embodiments corresponding to the operation 102. A packaging component 210 is mounted on a carrier 220. More specifically, the packaging component 210 is glued on an upper surface of the carrier 220 by employing an adhesive layer 230. In some embodiments, the packaging component 210 is alternatively referred to as an interposer that includes an interposer substrate 212 and conductive vias 214 embedded in the interposer substrate 212. In some embodiments, the interposer substrate 212 includes silicon, glass, and/or the like. In some embodiments, the adhesive layer 230 includes epoxy and/or the like. In some embodiments, the carrier 220 is formed of a wide variety of materials including glass, silicon, ceramics, polymers, and/or the like.

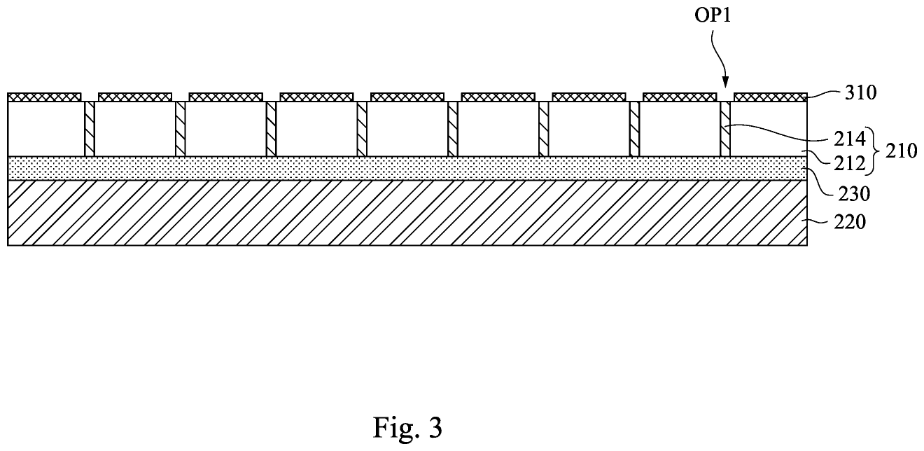

In the operation 104 of FIG. 1, a dielectric layer with openings is formed on the packaging component. FIG. 3 illustrates a cross-sectional view of some embodiments corresponding to the operation 104. A dielectric layer 310 is formed on the packaging component 210, in which openings OP1 penetrates through the dielectric layer 310 to expose the conductive vias 214. In some embodiments, the dielectric layer 310 includes polybenzoxazole (PBO), SU-8 photosensitive epoxy resin, film-type polymer materials, and/or the like. Formation of the openings OP1 in the dielectric layer 310 involves suitable lithography operations.

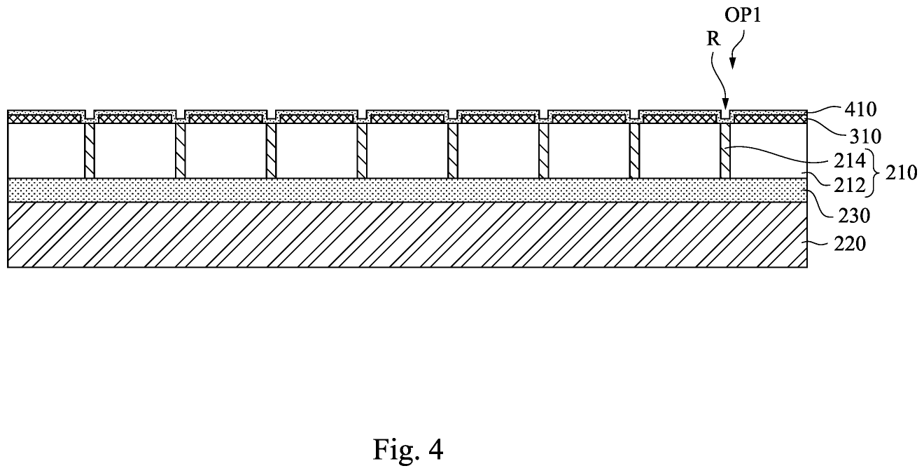

In the operation 106 of FIG. 1, a metal layer is formed on the dielectric layer. FIG. 4 illustrates a cross-sectional view of some embodiments corresponding to the operation 106. A metal seed layer 410 is formed on the dielectric layer 310. In some embodiments, the metal seed layer 410 conformally covers an upper surface of the dielectric layer 310 and inner surfaces of the openings OP1. Therefore, recesses R are formed in the openings OP1 and above the conductive vias 214. Each recess R is surrounded by the metal seed layer 410. In order to provide a nucleation site for the subsequent bulk metal deposition, the metal seed layer 410 is deposited on the dielectric layer 310. In some embodiments, the metal seed layer 410 may include copper, but other metals such as aluminum, copper-aluminum alloy, or other suitable conductive materials can be used as the seed layer 410. In some embodiments, the metal seed layer 410 is formed by using suitable fabrication methods such as physical vapor deposition (PVD) or chemical vapor deposition (CVD).

In the operation 108 of FIG. 1, a photoresist layer is formed on the metal layer, in which the photoresist layer includes an additive selected from the group consisting of a first heterocyclic compound containing a triazole ring, a second heterocyclic compound containing an imidazole ring, biphenyl thiol, biphenyl dithiol, benzenethiol, and benzenedithiol.

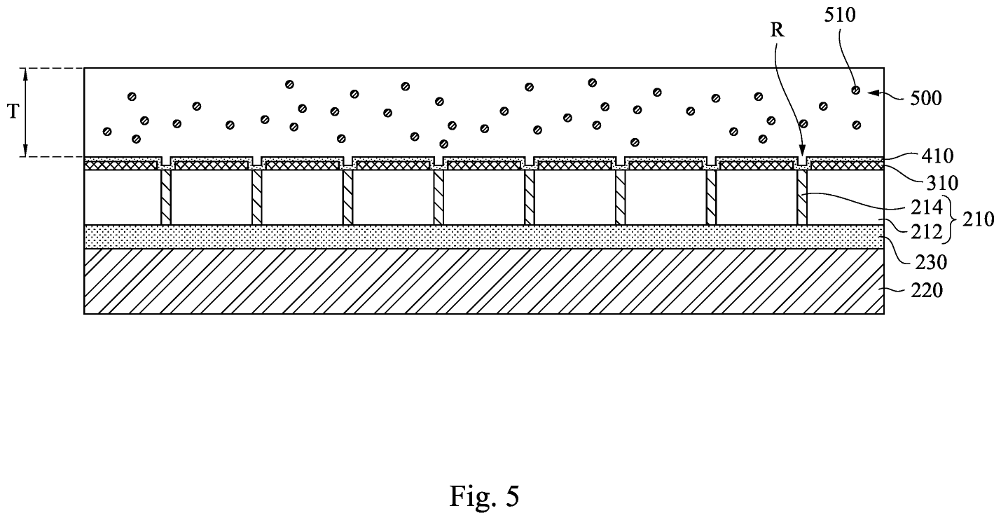

FIG. 5 illustrates a cross-sectional view of some embodiments corresponding to the operation 108. A photoresist layer 500 is formed on the metal seed layer 410. The photoresist layer 500 fills the recesses R. In some embodiments, the photoresist layer 500 is formed by coating a photoresist composition on the metal seed layer 410. In some embodiments, the photoresist layer 500 is alternatively referred to as a photoresist composition. The photoresist layer 500 includes a resin, a photoactive compound (PAC), an additive 510, and a solvent. The additive 510 is selected from the group consisting of a first heterocyclic compound containing a triazole ring, a second heterocyclic compound containing an imidazole ring, biphenyl thiol, biphenyl dithiol, benzenethiol, and benzenedithiol. In some embodiments, the photoresist layer 500 is a positive photoresist layer or a negative photoresist layer. In some embodiments, the photoresist layer 500 has a thickness T between 6 um and 10 um.

Since the additive 510 in the photoresist layer 500 has nitrogen (N) atom or sulfur (S) atom, which has electron-donating property, the additive 510 tends to adhere to the metal seed layer 410. In other words, the additive 510 may be adsorbed on an upper surface of the metal seed layer 410. In some embodiments, the photoresist layer 500 has an additive concentration decreasing as a distance from the metal seed layer 410 increases. In some embodiments, the photoresist layer 500 has a first additive concentration at the bottom portion and a second additive concentration at the top portion, and the first additive concentration is greater than the second additive concentration.

The additive 510 in the photoresist layer 500 has the triazole ring, the imidazole ring, and/or the benzene ring. These functional groups can protect the metal seed layer 410 and prevent the metal seed layer 410 from being damaged by a developer, and thus redistribution lines can be plated on the metal seed layer 410 having low roughness. Further details will be provided later. Furthermore, since the resin of in the photoresist layer 500 may contain a benzene ring, the properties of the functional groups are similar to that of the resin. The triazole ring, the imidazole ring, and the benzene ring of the additive 510 attract the resin because of π-π stacking interaction (also called pi stacking interaction). Accordingly, the resin may be firmly adhered on the metal seed layer 410 by the additive 510 because of the π-π stacking interaction. It can be known that the additive 510 acts as an adhesion promotor and a metal layer protector.

In some embodiments, the first heterocyclic compound includes a benzotriazole (BTA) moiety, and the second heterocyclic compound includes a benzimidazole (BIMD) moiety. In other words, the first heterocyclic compound may be a benzotriazole derivative, and the second heterocyclic compound may be a benzimidazole derivative.

In some embodiments, the additive 510 is selected from the group consisting of

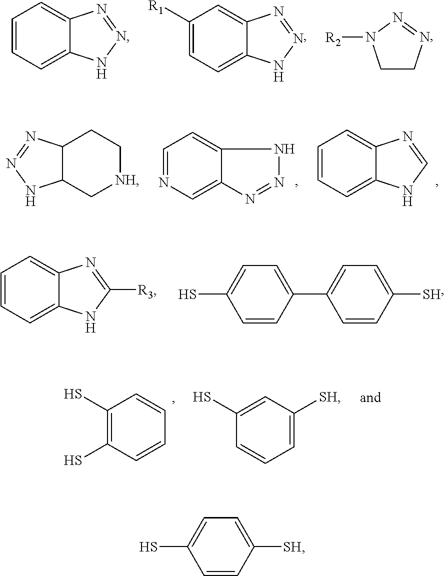

in which R₁ is C1-C5, R₂ is C1-C5, R₃ is C1-C16, F, Cl, Br, I, COOR₄, and R₄ is C1-C3. In some embodiments, R₁ and R₂ are independently methyl, ethyl, propyl, butyl, pentyl, or their isomers. In some embodiments, R₃ is methyl, ethyl, propyl, butyl, pentyl, hexyl, heptyl, octyl, nonyl, decyl, undecyl, dodecyl, tridecyl, tetradecyl, pentadecyl, hexadecyl, or their isomers. In some embodiments, R₄ is methyl, ethyl, propyl, or their isomers.

In some embodiments, the additive 510 is less than 10 wt % based on a total weight of the photoresist layer 500. In some embodiments, the additive 510 is 0.1 wt %-10 wt % based on the total weight of the photoresist layer 500. For example, the additive 510 is 0.1, 0.5, 1, 2, 3, 4, 5 6, 7, 8, 9, or 10 wt %. Since the additive 510 must be removed in the subsequent process, it is hard to fully remove the additive 510 in the subsequent process if the additive concentration is greater than 10 wt %, thereby adversely influencing the electroplating process of forming redistribution lines. In some embodiments, the resin is 50 wt %-70 wt % based on the total weight of the photoresist layer 500. The photoresist layer 500 including a resin concentration greater than 50 wt % can prevent the penetration of the developer into the photoresist layer 500. In some embodiments, the photoactive compound is 10 wt %-30 wt % based on the total weight of the photoresist layer 500. In some embodiments, the photoresist layer 500 further includes a cross-linker. For example, the cross-linker is 30 wt %-50 wt % based on the total weight of the photoresist layer 500. For example, the cross-linker is a acrylate cross-linker.

In some embodiments, the resin includes an acrylic resin, a novolac resin, or combinations thereof. In some embodiments, the resin includes a phenol-based resin, an acryl-based resin, or a mixture of the phenol-based resin and the acryl-based resin. For example, the resin includes a phenol novolac resin, an ortho-cresol novolac resin, a para-cresol novolac resin, an ortho-novolac resin, a para-novolac resin, a bisphenol novolac resin, a polyhydroxy novolac resin, a polyglutarimide resin, a copolymer of ethylenic unsaturated resins, a copolymer of acrylic acid esters, a polyester resin synthesized from polyhydric alcohols and polybasic acid compounds, a reaction product of epoxy resins, monocarboxylic acids, and polybasic acid anhydrides, or combinations thereof. However, the material of the resin is not limited thereto. The resin of the present disclosure may include other suitable resist used for a positive tone resist or a negative tone resist.

In some embodiments, the photoactive compound (PAC) includes a photoinitiator, a photoacid generator (PAG), a photobase (PBG) generator, a photo decomposable base (PDB), a free-radical generator, or combinations thereof. The PAC may be positive-acting or negative-acting. In some embodiments, the PAC is a photoacid generator, and the PAC includes halogenated triazine, onium salt, diazonium salt, aromatic diazonium salt, phosphonium salt, sulfonium salt, iodonium salt, imide sulfonate, oxime sulfonate, diazodisulfone, disulfone, o-nitrobenzylsulfonate, sulfonated ester, halogenated sulfonyloxy dicarboximide, diazodisulfone, α-cyanooxyamine-sulfonate, imidesulfonate, ketodiazosulfone, sulfonyldiazoester, 1,2-di(arylsulfonyl)hydrazine, nitrobenzyl ester, s-triazine derivativs, or combinations thereof.

In some embodiments, the solvent includes propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), or combinations thereof.

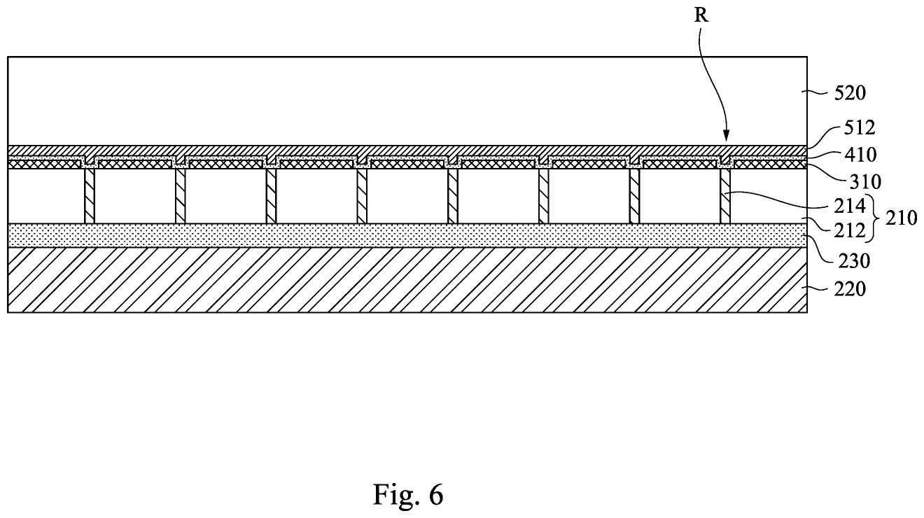

Reference is made to FIG. 6. In some embodiments, an additive layer 512 and a photoresist layer 520 are spontaneously formed from the photoresist layer 500 shown in FIG. 5, in which the additive layer 512 is between the metal seed layer 410 and the photoresist layer 520, and covers the upper surface of the metal seed layer 410. The photoresist layer 520 includes the resin, the photoactive compound, and the solvent. In some embodiments, the photoresist layer 520 further includes the additive 510. In some embodiments, the additive 510 adsorbed on the upper surface of the metal seed layer 410 forms the additive layer 512. As shown in FIG. 6, the additive layer 512 fills the recesses R. However, in some other embodiments, the recesses R may not be fully filled by the additive layer 512 (not shown). For example, the additive layer 512 conformally covers the metal seed layer 410 and the recesses R. In some embodiments, the additive layer 512 has a thickness less than 10 nm.

The additive layer 512 has the triazole ring, the imidazole ring, and/or the benzene ring. These functional groups can protect the metal seed layer 410 and prevent the metal seed layer 410 from being damaged by a developer. Furthermore, since the resin in the photoresist layer 520 may contain a benzene ring, the properties of the functional groups in the additive layer 512 are similar to that of the resin. The functional groups in the additive layer 512 attract the resin in the photoresist layer 520 because of the π-π stacking interaction. Accordingly, the photoresist layer 520 may be firmly adhered on the metal seed layer 410 by the additive layer 512 due to the π-π stacking interaction. It can be known that the additive layer 512 acts as an adhesion promotor and a metal layer protector.

In the operation 110 of FIG. 1, the photoresist layer is exposed to an actinic radiation. In some embodiments, the actinic radiation is i-light, ArF light, KrF light, an extreme ultraviolet (EUV), or a deep ultraviolet (DUV). Typically, the chemical properties of the photoresist regions struck by incident radiation change in a manner that depends on the type of photoresist used. The photoresist layer is either a positive tone resist or a negative tone resist. A positive tone resist refers to a photoresist material that when exposed to the actinic radiation becomes soluble in a developer, while the region of the photoresist that is non-exposed (or exposed less) is insoluble in the developer. A negative tone resist, on the other hand, refers to a photoresist material that when exposed to the actinic radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

In the operation 112 of FIG. 1, the photoresist layer is developed by a developer to form holes in the photoresist layer. In the operation 114 of FIG. 1, portions of the additive are exposed from the holes.

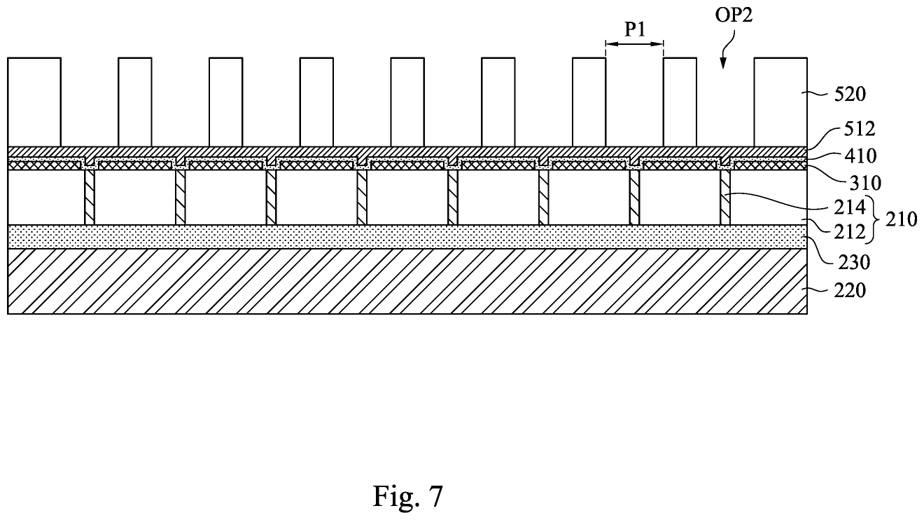

FIG. 7 illustrates a cross-sectional view of some embodiments corresponding to the operations 112 and 114. As shown in FIG. 7, after exposing, the photoresist layer 520 is developed by a developer to form holes OP2 in the photoresist layer 520. Whether a photoresist layer 520 is a positive tone or negative tone may depend on the type of developer used to develop the photoresist layer 520. For example, some positive tone photoresists provide a positive pattern, when the developer is an aqueous-based developer, such as a tetramethylammonium hydroxide (TMAH) solution, which is a strong base. The exposed regions are removed by the developer. On the other hand, the same photoresist provides a negative pattern, when the developer is an organic solvent, such as n-butyl acetate (nBA). The unexposed regions are removed by the developer.

As shown in FIG. 7, after developing, portions of the additive layer 512 are exposed from the holes OP2 in the photoresist layer 520. Since the additive layer 512 covers the metal seed layer 410, during an entire period of developing the photoresist layer 520 by the developer, the metal seed layer 410 is always separated from the developer by portions of the additive layer 512. The metal seed layer 410 may not be damaged by the developer, such as TMAH, due to the protection of the additive layer 512. Therefore, the upper surface of the metal seed layer 410 has a low roughness, and the photoresist layer 520 that is patterned does not easily collapse and peel away from the metal seed layer 410. The photoresist layer 520 can be firmly adhered to the metal seed layer 410. If the metal seed layer 410 was not covered by the additive layer 512, the metal seed layer 410 may be damaged by the developer and become rough, and the photoresist layer 520 may become fragile.

In some embodiments, a pitch P1 between adjacent two portions of the photoresist layer 520 is less than 3 urn. In some embodiments, the hole OP2 have an aspect ratio (i.e., ratio of hole depth to hole width/diameter) between about 2 and about 5. The greater aspect ratio is, the easier a photoresist layer collapse and peel away from a metal seed layer. However, as mentioned previously, the photoresist layer 520 can be firmly adhered on the metal seed layer 410 by the additive layer 512 due to the π-π stacking interaction. Therefore, even if the holes OP2 of the photoresist layer 520 have high aspect ratio, such as 4-5, the photoresist layer 520 that is patterned does not easily collapse and peel away from the metal seed layer 410.

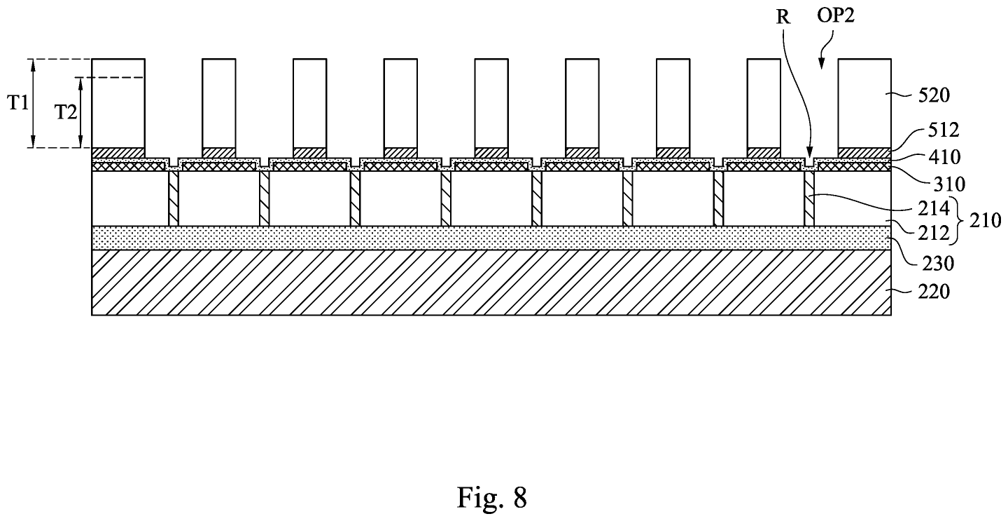

In the operation 116 of FIG. 1, the portions of the additive are removed to expose the metal layer. In some embodiments, the additive is removed by a dry etching process. FIG. 8 illustrates a cross-sectional view of some embodiments corresponding to the operation 116. The portions of the additive layer 512 that are exposed from the holes OP2 are removed to expose the metal seed layer 410 and the recesses R. Therefore, the exposed portions of the metal seed layer 410 can be used for growing redistribution lines in subsequent processes, e.g., plating. In some embodiments, the additive layer 512 is removed by O₂ plasma. In some embodiments, during removing the additive layer 512, portions of the photoresist layer 520 may also be removed. Therefore, a thickness T1 of the photoresist layer 520 decrease to a thickness T2 as shown in FIG. 8.

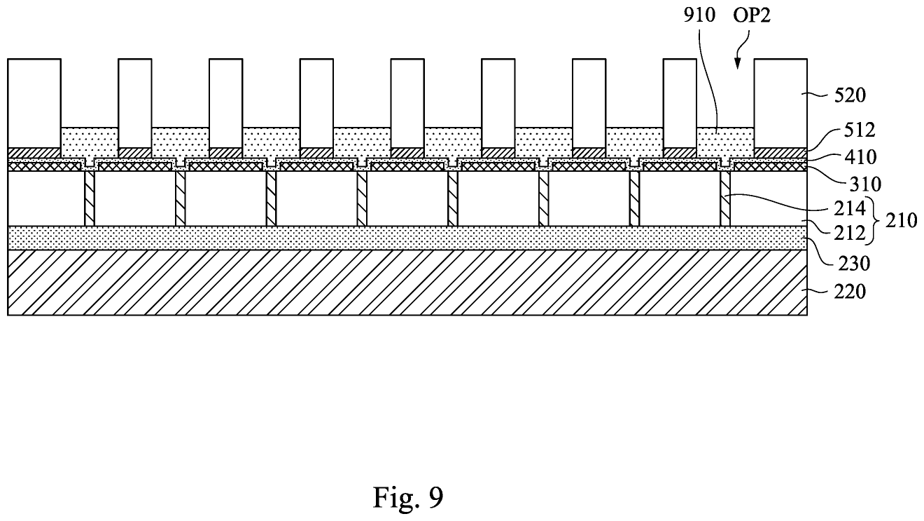

In the operation 118 of FIG. 1, redistribution lines are formed respectively in the holes and in direct contact with the metal layer. FIG. 9 illustrates a cross-sectional view of some embodiments corresponding to the operation 118. Redistribution lines 910 are formed in the respective holes OP2 and in direct contact with the metal seed layer 410 by forming a conductive material in the holes OP2. In some embodiments, the conductive material may be copper, copper alloys, aluminum, tungsten, silver, or combinations thereof. In some embodiments, the redistribution lines 910 are formed by an electroplating process using the metal seed layer 410 as a plating seed layer. In some embodiments, the holes OP2 are not fully filled by the redistribution lines 910.

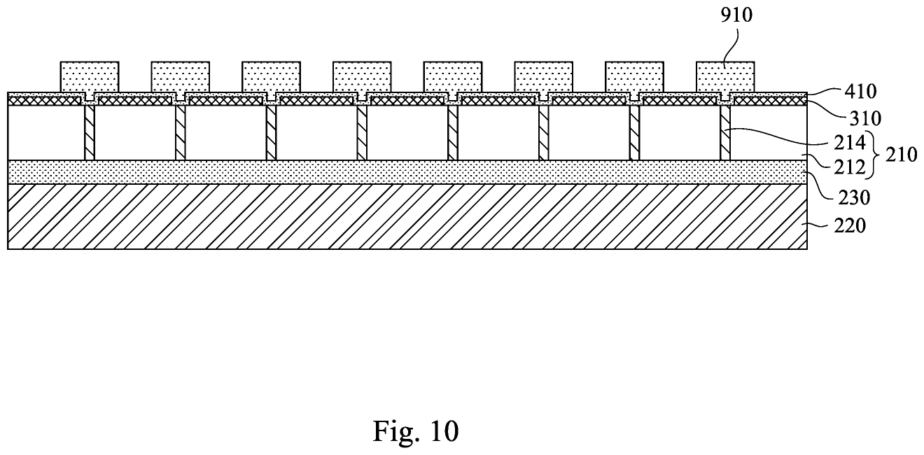

In the operation 120 of FIG. 1, the photoresist layer and the additive that is under the photoresist layer are removed. FIG. 10 illustrates a cross-sectional view of some embodiments corresponding to the operation 120. The photoresist layer 520 and the additive layer 512 that is under the photoresist layer 500 are removed to expose the metal seed layer 410. In some embodiments, the photoresist layer 500 is wet stripped. In some embodiments, the additive layer 512 is removed by a dry etching process with O₂ plasma.

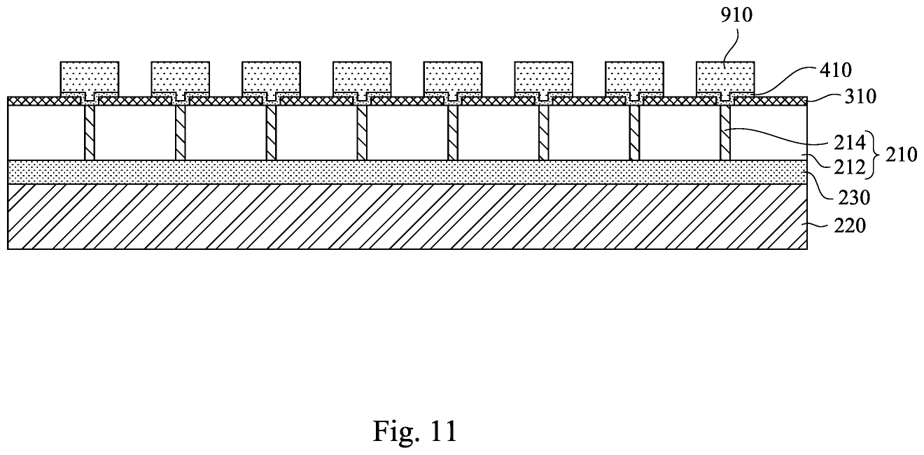

In the operation 122 of FIG. 1, portions of the metal layer are removed to expose the dielectric layer. FIG. 11 illustrates a cross-sectional view of some embodiments corresponding to the operation 122. Portions of the metal seed layer 410 that are exposed between the redistribution lines 910 are removed to expose the dielectric layer 310.

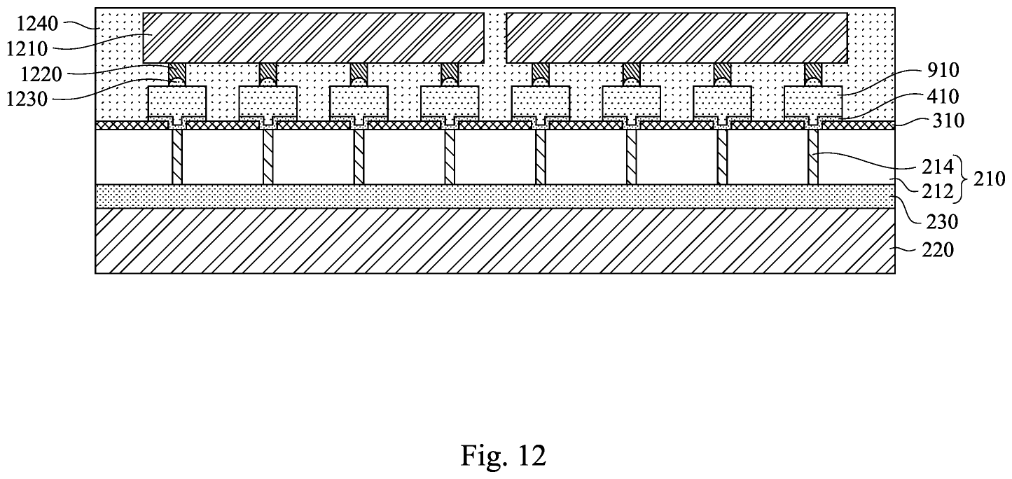

In the operation 124 of FIG. 1, an integrated circuit die is bonded on the packaging component. FIG. 12 illustrates a cross-sectional view of some embodiments corresponding to the operation 124. An integrated circuit die 1210 is bonded on the packaging component 210 through interconnect components including metal pillar bumps 1220, micro bumps 1230, the redistribution lines 910, and the metal seed layer 410. More specifically, each micro bump 1230 of the integrated circuit die 1210 is in direct contact with the redistribution lines 910. Therefore, the integrated circuit die 1210 is electrically connected to the packaging component 210. In some embodiments, a reflow process is performed so that the integrated circuit die 1210 is connected to the interposer 210 through the melted micro bumps. Furthermore, an encapsulation layer 1240 is formed on top of the packaging component 210 to protect the redistribution lines 910 from erosion. In addition, the encapsulation layer 1240 is thick enough to mechanically support the integrated circuit die 1210 in the subsequent fabrication steps. As such, the structure above the adhesive layer 230 can be detached from the carrier 220.

In some embodiments, the integrated circuit die 1210 may comprise basic semiconductor layers such as active circuit layers, substrate layers, inter-layer dielectric (ILD) layers and inter-metal dielectric (IMD) layers (not shown). The integrated circuit die 1210 may comprise a silicon substrate. Alternatively, the integrated circuit die 1210 may comprise a silicon-on-insulator substrate. The integrated circuit die 1210 may further comprise a variety of electrical circuits (not shown). The electrical circuits formed in the integrated circuit die 1210 may be any type of circuitry suitable for a particular application. In some embodiments, the electrical circuits may include various n-type metal-oxide semiconductor (NMOS) and/or p-type metal-oxide semiconductor (PMOS) devices such as transistors, capacitors, resistors, diodes, photo-diodes, fuses and the like. The electrical circuits may be interconnected to perform one or more functions. The functions may include memory structures, processing structures, sensors, amplifiers, power distribution, input/output circuitry or the like. One of ordinary skill in the art will appreciate that the above examples are provided for illustrative purposes only to further explain applications of the present disclosure and are not meant to limit the present disclosure in any manner.

In some embodiments, the encapsulation layer 1240 may be formed of underfill materials. In some embodiments, the underfill material may be an epoxy, which is dispensed at the gap between the interposer 210 and the integrated circuit die 1210. The epoxy may be applied in a liquid form, and may harden after a curing process. In accordance with some other embodiments, the encapsulation layer 1240 may be formed of curable materials such as polymer based materials, resin based materials, polyimide, epoxy and any combinations of thereof. The encapsulation layer 1240 can be formed by a spin-on coating process, dry film lamination process and/or the like.

Alternatively, the encapsulation layer 1240 may be a molding compound layer The molding compound layer may be formed of curable materials such as polymer based materials, resin based materials, polyimide, epoxy and any combinations of thereof. The molding compound layer can be formed by a spin-on coating process, an injection molding process and/or the like. In order to reliably handle the integrated circuit die 1210 mounted on top of the interposer 210 during subsequent fabrication process steps such as a backside fabrication process of the interposer 210, the molding compound layer is employed to keep the interposer 210 and the integrated circuit die 1210 on top of the interposer 210 from cracking, bending, warping and/or the like.

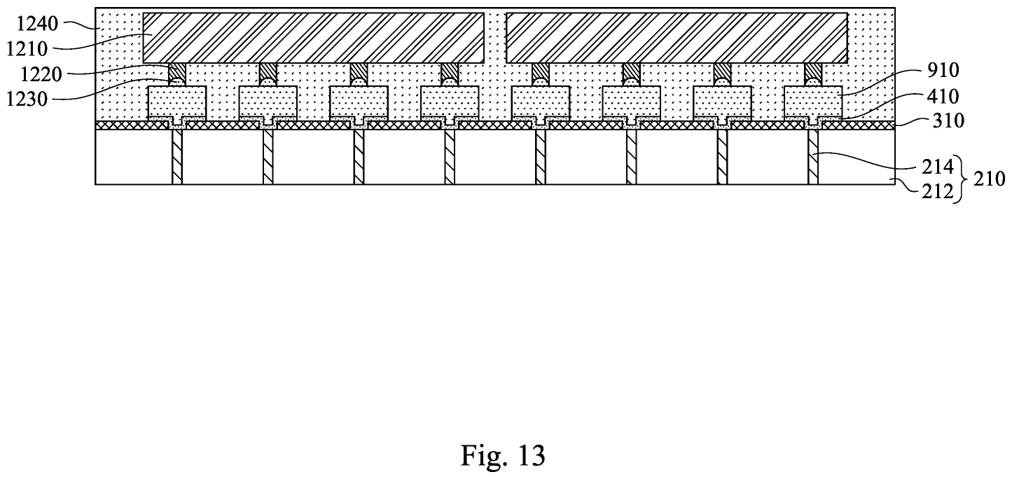

In the operation 126 of FIG. 1, the carrier is removed. FIG. 13 illustrates a cross-sectional view of some embodiments corresponding to the operation 126. The carrier 220 is removed and detached from the packaging component 210. A variety of detaching processes may be employed to separate the structure above the adhesive layer 230 from the carrier 220. In some embodiments, the detaching processes include using a chemical solvent or a UV exposure.

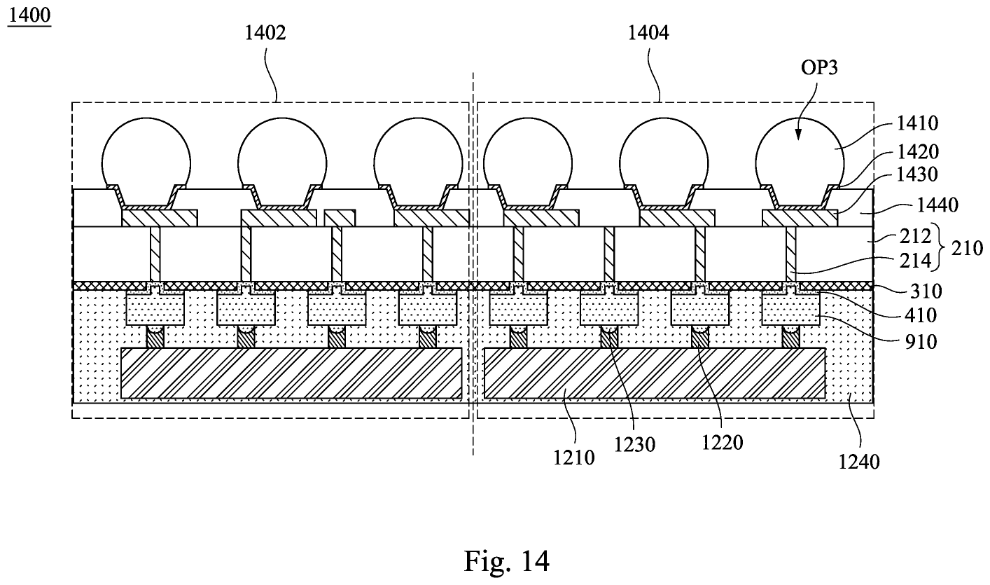

In the operation 128 of FIG. 1, bump structures are formed on the packaging component. FIG. 14 illustrates a cross-sectional view of some embodiments corresponding to the operation 128. Bump structures 1410, under bump metallization structures 1420, redistribution lines 1430, and a dielectric layer 1440 are formed on the packaging component 210 to form a semiconductor structure 1400 as shown in FIG. 14. More specifically, the redistribution lines 1430 are formed respectively in direct contact with the conductive vias 214. The dielectric layer 1440 with openings OP3 is formed on the redistribution lines 1430, in which the redistribution lines 1430 are exposed from the openings OP3. The under bump metallization structures 1420 are formed in the openings OP3. The bump structures 1410 are formed on the under bump metallization structures 1420. The under bump metallization structures 1420 may help to prevent diffusion between the bump structures 1410 and the packaging component 210, while providing a low resistance electrical connection. The bump structures 1410 may provide an effective way to connect with external circuits (not shown). In some embodiments, the bump structures 1410 are solder balls. In some other embodiments, the bump structures 1410 are land grid array (LGA) pads (not shown). In some embodiments, the redistribution lines 1430 include conductive materials such as copper, copper alloys, aluminum, tungsten, silver, or combinations thereof. Afterwards, the structure as shown in FIG. 14 will be subject to a singulation process to be separated into individual chip packages 1402 and 1404. The singulation process may be, for example, a dicing process.

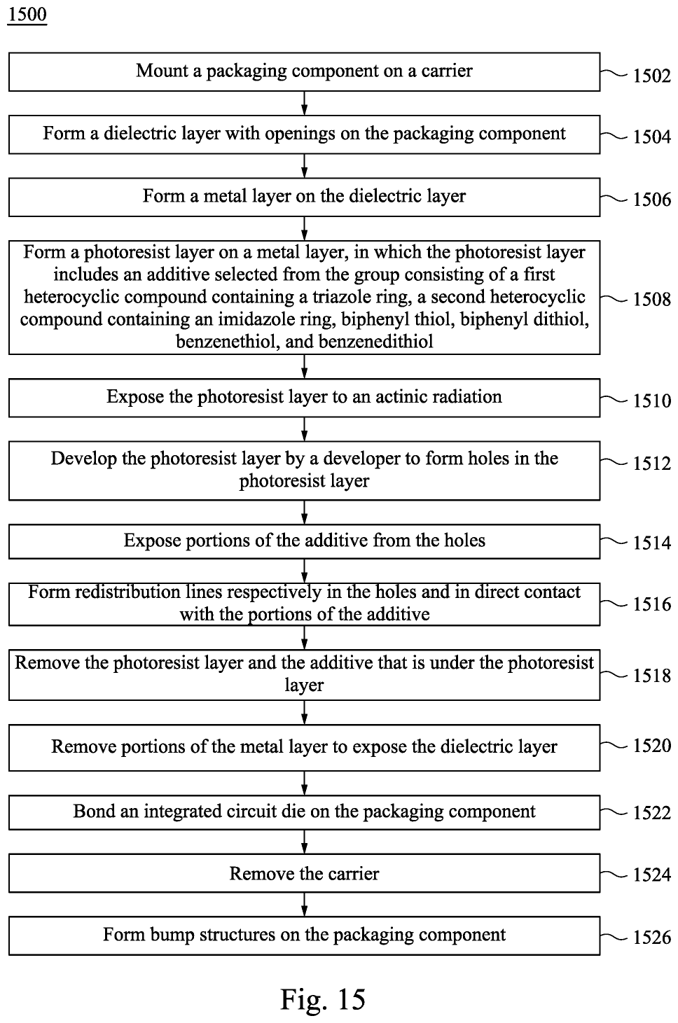

FIG. 15 illustrates a method 1500 for manufacturing a semiconductor structure in accordance with some embodiments. The method 1500 includes operations 1502, 1504, 1506, 1508, 1510, 1512, 1514, 1516, 1518, 1520, 1522, 1524, and 1526. Although the method 1500 is illustrated and/or described as a series of operations or events, it will be appreciated that the method 1500 is not limited to the illustrated ordering or operations. Thus, in some embodiments, the operations may be carried out in different orders than illustrated, and/or may be carried out concurrently. Further, in some embodiments, the illustrated operations or events may be subdivided into multiple operations or events, which may be carried out at separate times or concurrently with other operations or sub-operations. In some embodiments, some illustrated operations or events may be omitted, and other un-illustrated operations or events may be included.

The operation 1502 of the method 1500 is mounting a packaging component on a carrier. The method 1500 continues with the operation 1504 in which a dielectric layer with openings is formed on the packaging component. The method 1500 continues with the operation 1506 in which a metal layer is formed on the dielectric layer. The method 1500 continues with the operation 1508 in which a photoresist layer is formed on a metal layer, in which the photoresist layer includes an additive selected from the group consisting of a first heterocyclic compound containing a triazole ring, a second heterocyclic compound containing an imidazole ring, biphenyl thiol, biphenyl dithiol, benzenethiol, and benzenedithiol. The method 1500 continues with the operation 1510 in which the photoresist layer is exposed to an actinic radiation. The embodiments of the operations 1502, 1504, 1506, 1508, and 1510 may be referred to the embodiments of operations 102, 104, 106, 108, and 110 and FIGS. 1-6.

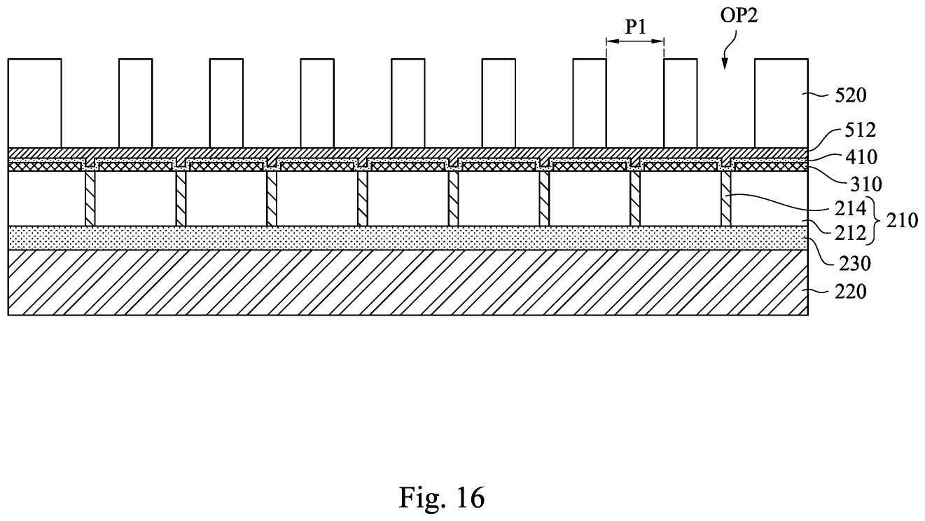

FIGS. 16-19 show exemplary sequential processes for manufacturing a semiconductor structure in accordance with some embodiments.

In the operation 1512 of FIG. 15, the photoresist layer is developed by a developer to form holes in the photoresist layer. In the operation 1514 of FIG. 15, portions of the additive are exposed from the holes. FIG. 16 illustrates a cross-sectional view of some embodiments corresponding to the operations 1512 and 1514. As shown in FIG. 16, the photoresist layer 520 is developed by a developer to form the holes OP2 in the photoresist layer 520, and portions of the additive layer 512 are exposed from the holes OP2. During an entire period of developing the photoresist layer 520 by the developer, since the metal seed layer 410 is always separated from the developer by portions of the additive layer 512, the metal seed layer 410 may not be damaged by the developer due to the protection of the additive layer 512. Moreover, as previously mentioned, the photoresist layer 520 can be firmly adhered to the metal seed layer 410 by the additive layer 512. Accordingly, the additive layer 512 acts as an adhesion promotor and a metal layer protector. The embodiments of the operations 1512 and 1514 may be referred to the embodiments of the operations 112 and 114 and FIG. 7.

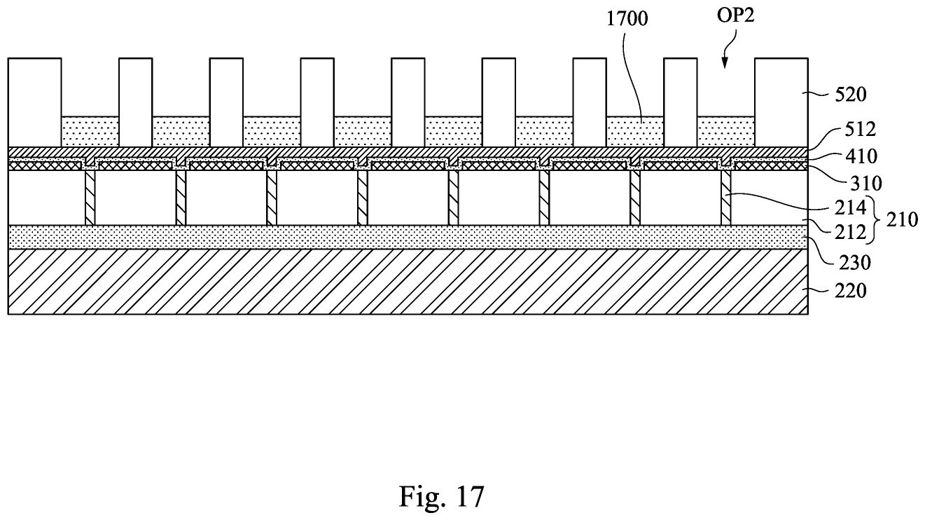

In the operation 1516 of FIG. 15, redistribution lines are formed respectively in the holes and in direct contact with the portions of the additive. FIG. 17 illustrates a cross-sectional view of some embodiments corresponding to the operation 1516. Redistribution lines 1700 are formed respectively in the holes OP2 and in direct contact with the additive layer 512. In other words, before forming the redistribution lines 1700, the additive layer 512 exposed from the holes OP2 is not removed. Therefore, the manufacturing process can be simplified. In some embodiments, the redistribution lines 1700 are formed by an electroplating process by using the additive layer 512 as a plating seed layer. In some embodiments, the additive layer 512 has a thickness less than about 10 nm. Because the additive layer 512 is thin enough, the additive layer 512 does not influence the formation of the redistribution lines 1700 during the electroplating process. As shown in FIG. 17, the additive layer 512 is disposed between the metal seed layer 410 and the redistribution lines 1700.

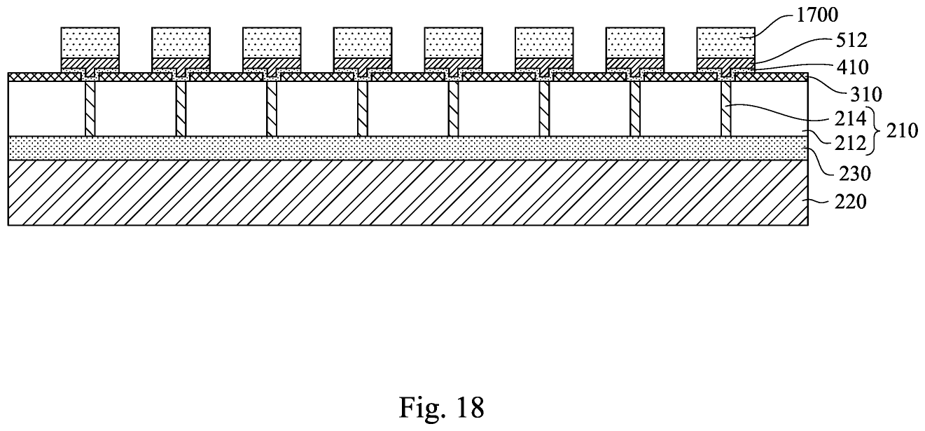

In the operation 1518 of FIG. 15, the photoresist layer and the additive that is under the photoresist layer are removed. In the operation 1520 of FIG. 15, portions of the metal layer are removed to expose the dielectric layer. FIG. 18 illustrates a cross-sectional view of some embodiments corresponding to the operations 1518 and 1520. The photoresist layer 520 and the additive layer 512 that is under the photoresist layer 500 are removed. Portions of the metal seed layer 410 exposed between the redistribution lines 1700 are removed to expose the dielectric layer 310 as shown in FIG. 18. It is noted that portions of the additive layer 512 leave between the metal seed layer 410 and the redistribution lines 1700. The embodiments of the operations 1518 and 1520 may be referred to the embodiments of the operations 120 and 122 and FIGS. 10-11.

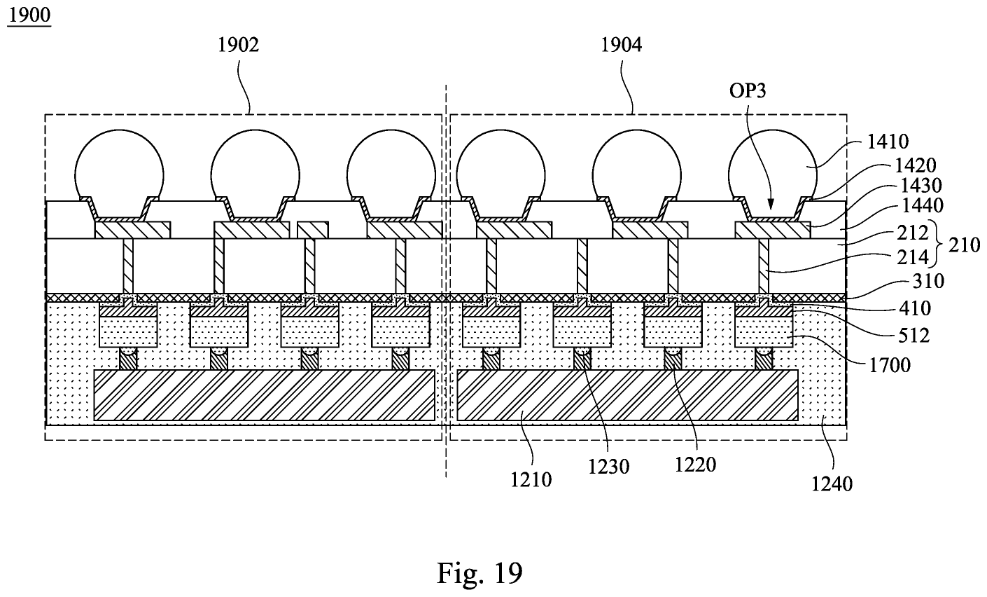

In the operation 1522 of FIG. 15, an integrated circuit die is bonded on the packaging component. In the operation 1524 of FIG. 15, the carrier 220 is removed. In the operation 1526 of FIG. 15, bump structures are formed on the packaging component. FIG. 19 illustrates a cross-sectional view of some embodiments corresponding to the operations 1522, 1524, and 1526. The embodiments of the operations 1522, 1524, and 1526 may be referred to the embodiments of operations 124, 126, and 128 and FIGS. 12-14.

As shown in FIG. 19, the bump structures 1410, the under bump metallization structures 1420, the redistribution lines 1430, and the dielectric layer 1440 are formed on the packaging component 210 to form a semiconductor structure 1900 as shown in FIG. 19. It is noted that the additive layer 512 has portions disposed between the metal seed layer 410 and the redistribution lines 1700. In some embodiments, each portion of the additive layer 512 has a T-shaped profile. In some embodiments, each portion of the additive layer 512 has a sidewall substantially aligned with a sidewall of the redistribution lines 1700. In some embodiments, each portion of the additive layer 512 has a sidewall substantially aligned with a sidewall of the metal seed layer 410. Afterwards, the structure as shown in FIG. 19 will be subject to a singulation process to be separated into individual chip packages 1902 and 1904. The singulation process may be, for example, a dicing process.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage of some embodiments is that the photoresist layer can be firmly adhered on the metal layer by the additive, and therefore after the photoresist layer is patterned, the patterned photoresist layer does not easily collapse and peel away from the metal layer. Another advantage of some embodiments is that the additive can protect the metal layer and prevent the metal layer from being damaged by a developer, and thus the redistribution lines can be plated on the metal layer having low roughness. The patterned photoresist layer also does not easily collapse because of the low roughness of the metal layer.

In some embodiments, a method of manufacturing a semiconductor structure includes the following operations. A photoresist layer is formed on a metal layer, in which the photoresist layer includes an additive selected from the group consisting of a first heterocyclic compound containing a triazole ring, a second heterocyclic compound containing an imidazole ring, biphenyl thiol, biphenyl dithiol, benzenethiol, and benzenedithiol. The photoresist layer is exposed to an actinic radiation. The photoresist layer is developed by a developer to form holes in the photoresist layer. Redistribution lines are formed respectively in the holes by an electroplating process.

In some embodiments, a method of manufacturing a semiconductor structure includes the following operations. A photoresist composition is coated on a metal layer, in which the photoresist composition includes an additive selected from the group consisting of a first heterocyclic compound containing a triazole ring, a second heterocyclic compound containing an imidazole ring, biphenyl thiol, biphenyl dithiol, benzenethiol, and benzenedithiol. An additive layer and a photoresist layer are spontaneously formed from the photoresist composition, in which the additive layer is between the metal layer and the photoresist layer and covers an upper surface of the metal layer. The photoresist layer is exposed to an actinic radiation. The photoresist layer is developed to form holes in the photoresist layer. Redistribution lines are formed respectively in the holes by an electroplating process.

In some embodiments, a photoresist composition includes a resin, a photoactive compound, an additive, and a solvent. The additive is selected from the group consisting of a first heterocyclic compound containing a triazole ring, a second heterocyclic compound containing an imidazole ring, biphenyl thiol, biphenyl dithiol, benzenethiol, and benzenedithiol.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor structure, comprising:
forming a photoresist layer on a metal layer, wherein the photoresist layer comprises an additive selected from the group consisting of a first heterocyclic compound containing a triazole ring, a second heterocyclic compound containing an imidazole ring, biphenyl thiol, biphenyl dithiol, benzenethiol, and benzenedithiol;
exposing the photoresist layer to an actinic radiation;
developing the photoresist layer by a developer to form holes in the photoresist layer; and
forming redistribution lines respectively in the holes by an electroplating process.

2. The method of claim 1, wherein the photoresist layer has an additive concentration decreasing as a distance from the metal layer increases.

3. The method of claim 1, wherein the additive is adsorbed on an upper surface of the metal layer.

4. The method of claim 3, wherein during an entire period of developing the photoresist layer by the developer, the holes the metal layer is always separated from the developer by portions of the additive.

5. The method of claim 4, further comprising:
removing the portions of the additive to expose the metal layer, wherein the redistribution lines are formed in contact with the metal layer.

6. The method of claim 5, wherein the additive is removed by a dry etching process.

7. The method of claim 4, wherein forming the redistribution lines respectively in the holes comprises forming the redistribution lines respectively in direct contact with the portions of the additive.

8. The method of claim 1, wherein the first heterocyclic compound comprises a benzotriazole moiety, and the second heterocyclic compound comprises a benzimidazole moiety.

9. The method of claim 1, wherein the additive is selected from the group consisting of 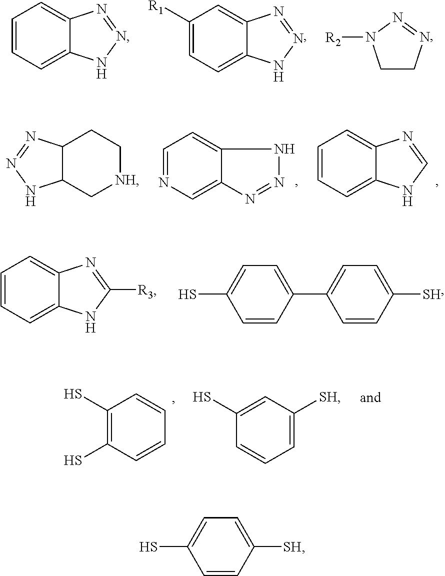
wherein R₁ is C1-C5, R₂ is C1-C5, R₃ is C1-C16, F, Cl, Br, I, COOR₄, and R₄ is C1-C3.

10. The method of claim 1, wherein the holes have an aspect ratio from about 2 to about 5.

11. A method of manufacturing a semiconductor structure, comprising:
coating a photoresist composition on a metal layer, wherein the photoresist composition comprises an additive selected from the group consisting of a first heterocyclic compound containing a triazole ring, a second heterocyclic compound containing an imidazole ring, biphenyl thiol, biphenyl dithiol, benzenethiol, and benzenedithiol;
spontaneously forming an additive layer and a photoresist layer from the photoresist composition, wherein the additive layer is between the metal layer and the photoresist layer and covers an upper surface of the metal layer;
exposing the photoresist layer to an actinic radiation;
developing the photoresist layer to form holes in the photoresist layer; and
forming redistribution lines respectively in the holes by an electroplating process.

12. The method of claim 11, wherein after developing the photoresist layer, portions of the additive layer are exposed at bottoms of the holes in the photoresist layer.

13. The method of claim 12, further comprising:
removing the portions of the additive layer to expose the metal layer, wherein the redistribution lines are formed in direct contact with the metal layer.

14. The method of claim 12, wherein forming the redistribution lines respectively in the holes comprises forming the redistribution lines respectively in direct contact with the portions of the additive layer.

15. The method of claim 11, wherein the additive is selected from the group consisting of 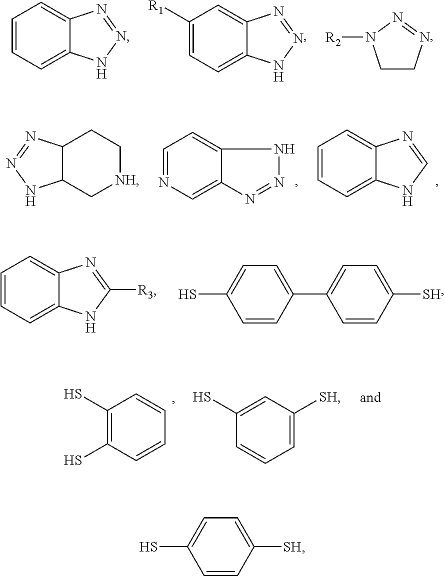
wherein R₁ is C1-C5, R₂ is C1-C5, R₃ is C1-C16, F, Cl, Br, I, COOR₄, and R₄ is C1-C3.

16. The method of claim 11, wherein the additive layer has a thickness less than 10 nm.

17. A photoresist composition, comprising:
a resin;
a photoactive compound;
an additive selected from the group consisting of a first heterocyclic compound containing a triazole ring, a second heterocyclic compound containing an imidazole ring, biphenyl thiol, biphenyl dithiol, benzenethiol, and benzenedithiol; and
a solvent.

18. The photoresist composition of claim 17, wherein the additive is 0.1 wt %-10 wt % based on a total weight of the photoresist composition.

19. The photoresist composition of claim 17, wherein the first heterocyclic compound comprises a benzotriazole moiety, and the second heterocyclic compound comprises a benzimidazole moiety.

20. The photoresist composition of claim 17, wherein the additive is selected from the group consisting of 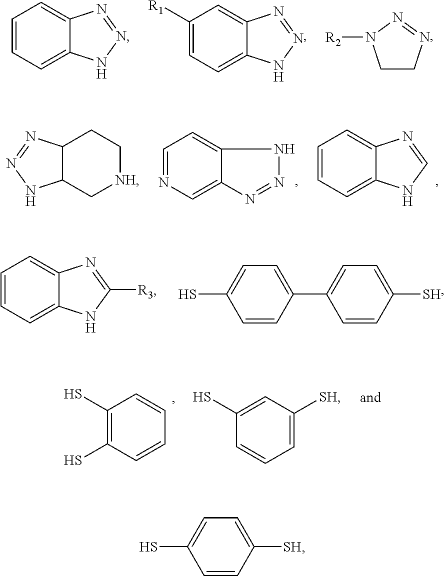
wherein R₁ is C1-C5, R₂ is C1-C5, R₃ is C1-C16, F, Cl, Br, I, COOR₄, and R₄ is C1-C3.
